(19) United States
(12) Patent Application Publication
(10) Pub. No.: US 2009/0237126 A1
(43) Pub. Date: Sep. 24, 2009

(54) GATE DRIVER FOR SWITCHING POWER MOSFET

(75) Inventor: Chin-Yang Chen, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: ELITE SEMICONDUCTOR MEMORY TECHNOLOGY INC., Hsinchu (TW)

(21) Appl. No.: 12/053,637

(22) Filed: Mar. 24, 2008

(51) Int. Cl. H03K 3/00

(52) U.S. Cl. 327/109

(57) ABSTRACT

A gate driver for switching power MOSFET including a MOS pair, a first conduction path, and a second conduction path is disclosed. The MOS pair electrically coupling gate of the power MOSFET, for controlling turning on or turning off the power MOSFET. The first conduction path electrically couples to gate of the power MOSFET and the MOS pair, and has a constant resistance. The second conduction path electrically coupling to gate of the power MOSFET and the MOS pair, having variable resistance corresponding to gate voltage of the power MOSFET.

### FIELD OF THE INVENTION

The present invention relates generally to a gate driver, and more particularly to the gate driver for switching a power MOSFET.

### BACKGROUND OF THE INVENTION

Power MOSFETs are applied to support large current to a loading; therefore, it is important to ensure the turning on/off sequence of the power MOSFETs to avoid damages and power consumption caused by short circuit current passing through the power MOSFETs. For example, a class D amplifier includes an output stage constructed by two power MOSFETs, one is a power PMOS and the other is a power NMOS, to support current alternately. Please refer to FIG. 1, it shows a class D amplifier output stage 10 including an output stage 15, and the output stage 15 includes a power PMOS 20 and a power NMOS 25, which gate voltages are separately controlled by gate drivers 30 and 35. The gate drivers 30 and 35 cannot turn on the power PMOS 20 and the power NMOS 25 at the same time to avoid short circuit current from VDD to ground. In normal operation of the output stage 15, one of the power PMOS 20 and the power NMOS 25 is turned off, and in the transition time, the gate driver 30 and 35 turn off both the power PMOS 20 and the power NMOS 25 firstly and then turn on one of the power MOSFETs. In general, a long transition time causes larger output distortion (because both power MOSFETs are turned off while a shorter transition time causes strong EMI emission (because the loading is inductive). It is one objective of this invention to discover a control mechanism achieving balance, that is, finding a gate driver with appropriate transition time.

FIG. 2A and FIG. 2B respectively show voltage diagram of drain and gate voltages of power NMOS 25 shown in FIG. 1 with faster and slower gate voltage transition. It is well-known that MOSFET has a parasitic capacitor between drain and gate, therefore, when the gate voltage V_{G} approaches the NMOSFET's threshold voltage V_{TH}, the drain voltage V_{D} will rise. The gate voltage V_{G} is kept constant a period of time until the drain voltage V_{D} reaches a constant level. The total transition time equals to T₁ plus T₂, T₂ is proportional to T₁, so the transition time is dominated by T₁. In FIG. 2A, V_{G} and V_{D} changes rapidly resulting in shorter transition time but stronger EMI emission. In FIG. 2B, V_{G} and V_{D} changes slowly resulting in longer transition time but larger output distortion. In fact, it is necessary to solve the same issue of a power PMOS.

### SUMMARY OF THE INVENTION

A new gate driver is provided to drive a power MOSFET. The gate driver, including two different conduction paths to guide electric current flowing off the gate terminal of the power MOSFET, controls the transition time of the power MOSFET from turning on to off.

In embodiments, a gate driver for switching a power MOSFET is disclosed. The gate driver includes a MOS pair electrically coupling gate of the power MOSFET, a first conduction path electrically coupling to gate of the power MOSFET and the MOS pair, and a second conduction path electrically coupling to gate of the power MOSFET and the MOS pair. The MOS pair controls turning on or off the power MOSFET; the first conduction path has a constant resistance; and the second conduction path has variable resistance corresponding to gate voltage of the power MOSFET.

The above and other features of the present invention will be better understood from the following detailed description of the preferred embodiments of the invention that is provided in connection with the accompanying drawings.

### BRIEF DESCRIPTION OF THE DRAWINGS

The accompanying drawings illustrate preferred embodiments of the invention, as well as other information pertinent to the disclosure, in which:

FIG. 1 is a diagram of a class D amplifier output stage.

FIG. 2A is a voltage diagram of drain and gate voltages of power NMOS shown in FIG. 1 with rapid gate voltage transition.

FIG. 2B is voltage diagram of drain and gate voltages of power NMOS 25 shown in FIG. 1 with slow gate voltage transition.

FIG. 3 is a gate driver circuit of one embodiment of the invention.

FIG. 4 is resistance curve of a resistor and a NMOS operating at linear region.

FIG. 5 is voltage curve of gate voltages of power NMOS shown in FIG. 3.

FIG. 6 is a gate driver circuit of another embodiment of the invention.

FIG. 7 is resistance curve of a resistor and a PMOS operating at linear region.

FIG. 8 is voltage curve of gate voltages of power PMOS shown in FIG. 6.

### DETAILED DESCRIPTION

This description of the exemplary embodiments is intended to be read in connection with the accompanying drawings, which are to be considered part of the entire written description. In the description, relative terms such as “lower,” “upper,” “horizontal,” “vertical,”, “above,” “below,” “up,” “down,” “top” and “bottom” as well as derivatives thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

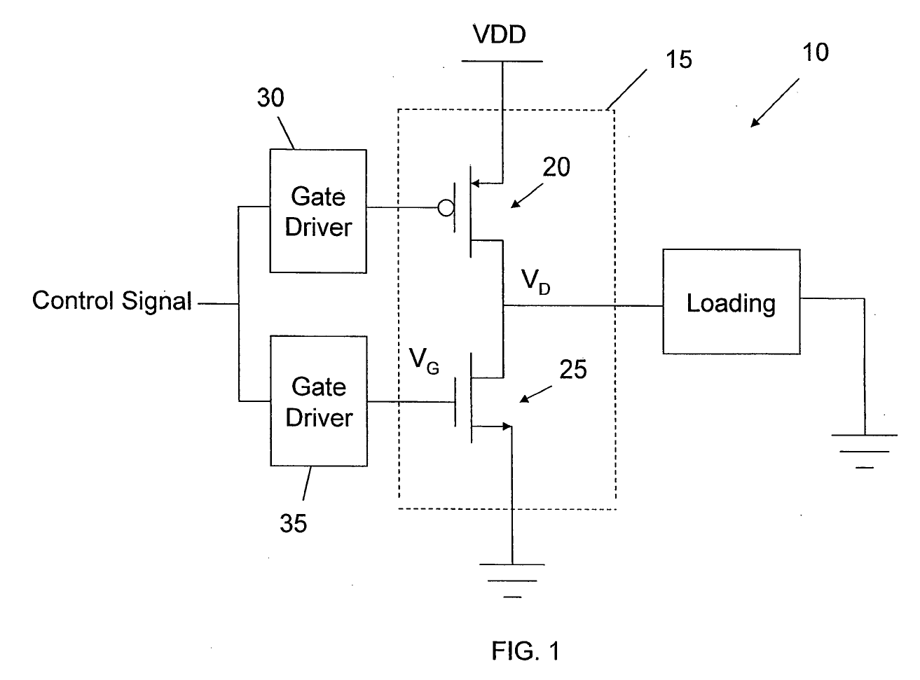

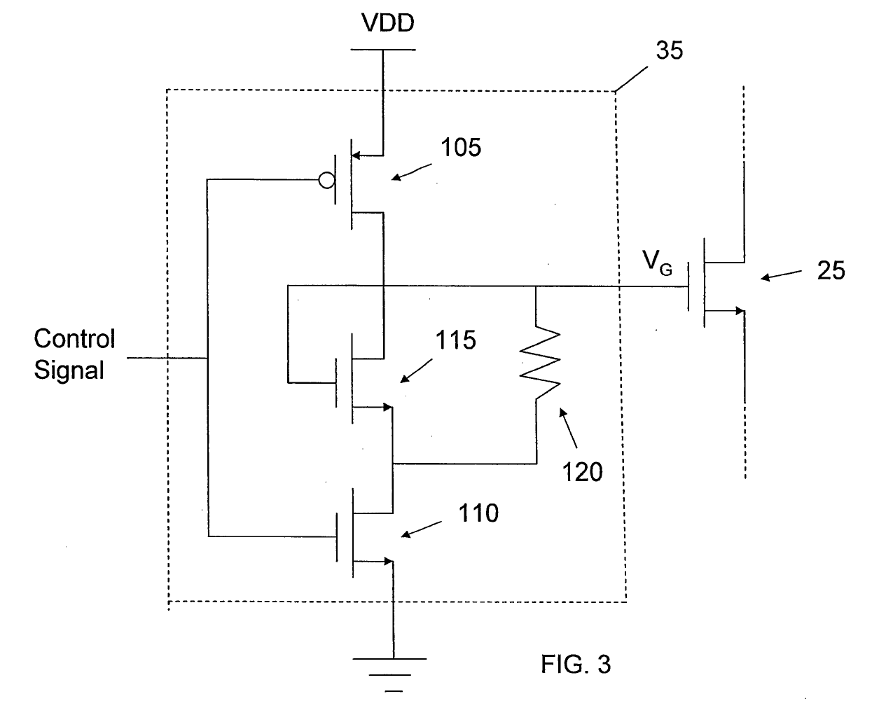

Please refer to FIG. 3, which is one embodiment of the gate driver disclosed in the invention. The power NMOS 25 is the same as that shown in FIG. 1. The gate driver 35 comprises a MOS pair, that is, PMOS 105 and NMOS 110, a NMOS 115, and a resistor 120. The gates of PMOS 105 and NMOS 10 are coupled together and are controlled by a control signal. Similar to an inverter, PMOS 105 and NMOS 110 cannot be turned on or off at the same time, i.e., there is always one been turned off and the other been turned on. The gate and drain of NMOS 115 are connected together and coupled to PMOS 105 and the gate of power NMOS 25, and the source of NMOS 115 is coupled to the drain of NMOS 110. This, configuration biases NMOS 115 in the linear region. As a result, NMOS 115 can be deemed a variable resistor, and the resistance of which is determined by gate voltage of the power NMOS 25. Briefly, a smaller power NMOS 25 gate voltage results in a greater resistance between drain and source terminals of the NMOS 115, and vice versa. In addition, one fixed resistor 120 is provided. One terminal of the resistor 120 is coupled to the gate of the power NMOS 25 and the other terminal is coupled together with the source of the NMOS 115 and the drain of NMOS 110. In practice, the resistor 120 can be a polysilicon resistor.

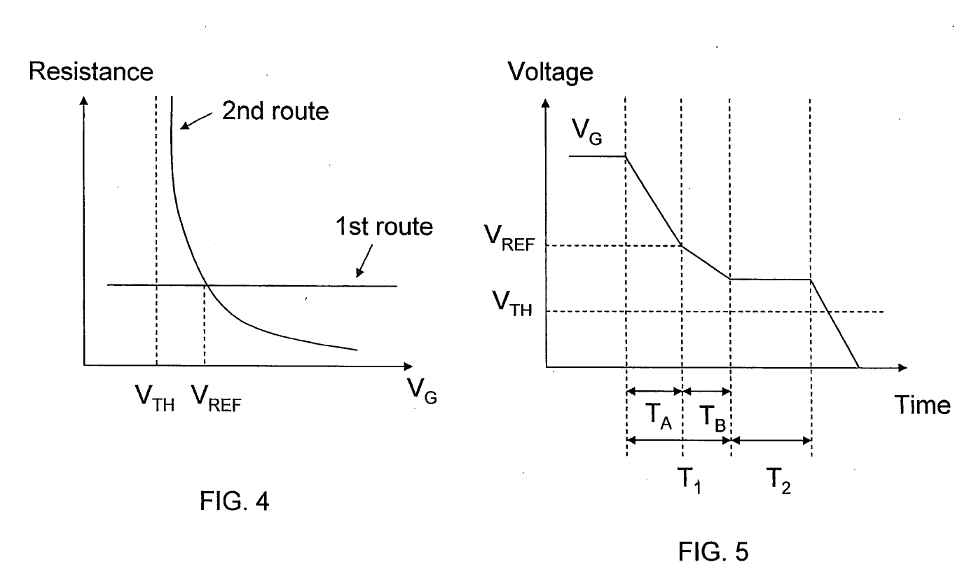

The NMOS 115 acts like a variable resistor but the resistor 120 has a constant resistant. They support two different conduction routes to charge or discharge the gate of power NMOS 25 to the drain of the NMOS 110. Please refer to FIG. 4, which is resistance curve of a resistor and a MOS operating in the linear region. The 1st route represents the resistor 120 shown in FIG. 3 and the 2nd route represents the NMOS 115 shown in FIG. 3. As FIG. 4 shows, resistance of the 2nd route is increased when the gate voltage V_{G} of the power NMOS 25 is decreased. If the gate voltage V_{G} drops approaching the threshold voltage V_{TH} of NMOS 115, resistance of NMOS 115 approaches infinity, while the resistance of the 1st route is always constant. The two curves cross each other when the-gate voltage V_{G} equals a reference voltage V_{REF}, that is, when the gate voltage V_{G} is greater than the reference voltage V_{REF}, resistance of the 1st route is greater than resistance of the 2nd route; when the gate voltage V_{G} is less than the reference voltage V_{REF}, resistance of the 2nd route is greater than resistance of the 1st route. Therefore, the resistor 120 and the NMOS 115 provide two conduction routes for current flow from the gate of the power NMOS 25 to the drain of the NMOS 110.

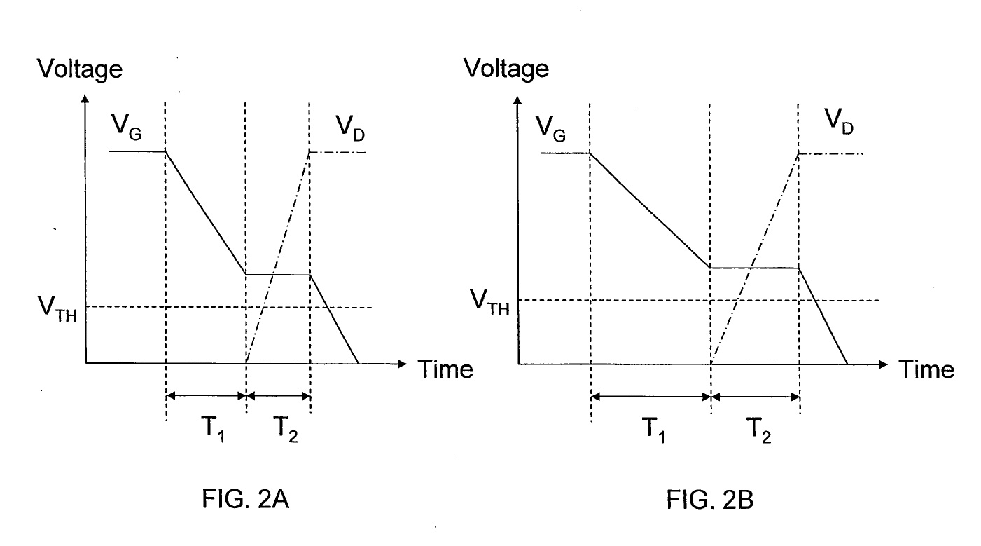

The current prefers to flow through the lower resistance conduction route. Therefore more current flows through the NMOS 115 when the gate voltage V_{G} is greater than the reference voltage V_{REF}, and less current flows through the resistor 120 when the gate voltage V_{G} is less than the reference voltage V_{REF}. Please refer to FIG. 5, which is a voltage diagram of gate voltages of power NMOS shown in FIG. 3 corresponding to this invention. T₁ of the gate voltage V_{G} curve shown in FIG. 5 is divided into two parts, T_{A} and T_{B} due to the two conduction routes provided in FIG. 3. At beginning, the gate voltage V_{G} is at high level. When the control signal changes from low to high, V_{G} starts dropping but still greater than the reference voltage V_{REF}, most charge stored at gate of the power NMOS 25 flows through the lower resistance conduction route, that is, the NMOS 115, to the NMOS 110 and then to ground. The gate voltage curve of this period T_{A} is shown in FIG. 5. Continuously, the gate voltage V_{G} still drops and less than the reference voltage V_{REF} but stops near the threshold voltage V_{TH}, most remaining charge stored at gate of the power NMOS 25 flows through the resistor 120 instead of the NMOS 115 to the NMOS 110 period T_{B}. Because T₁ is flexibly adjusted by T_{A} and T_{B}, T₁ shown in FIG. 5 is longer than T₁ shown in FIG. 2A but is shorter than T₁ shown in FIG. 2B. On the other side, T₂ keeps almost the same. Therefore, the transition time is controlled to balance the EMI issue and the output signal distortion.

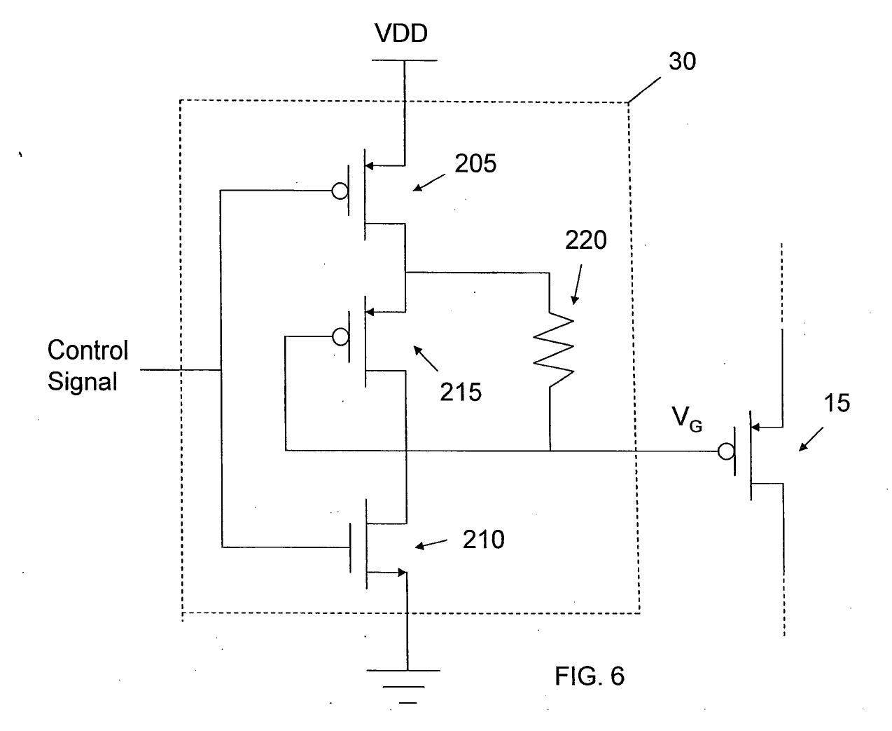

Please refer to FIG. 6, FIG. 6 is another embodiment of the gate driver disclosed in the invention. The power PMOS 15 is the same as shown in FIG. 1. The gate driver 30 comprises a MOS pair, that is, PMOS 205 and NMOS 210, a PMOS 215, and a resistor 220. The gates of PMOS 205 and NMOS 210 are coupled together and are controlled by a control signal. Similar to an inverter, PMOS 205 and NMOS 210 cannot be turned on or off at the same time. The gate and drain of PMOS 215 are connected together and coupled to NMOS 210 and the gate of power PMOS 15, and the source of PMOS 215 is coupled to the drain of PMOS 205. This configuration biases PMOS 215 in the linear region, so the PMOS 215 can be deemed as a variable resistor which the resistance is determined by gate voltage of the power PMOS 15. Briefly, a smaller power PMOS 15 gate voltage results in a smaller resistance between drain and source terminals of the PMOS 215, and vice versa. In addition, one fixed resistor 220 is provided. One terminal of the resistor 220 is coupled to the gate of the power PMOS 15 and the other terminal is coupled together with the source of the PMOS 215 and the drain of PMOS 205. In practice, the resistor 220 can be a polysilicon resistor.

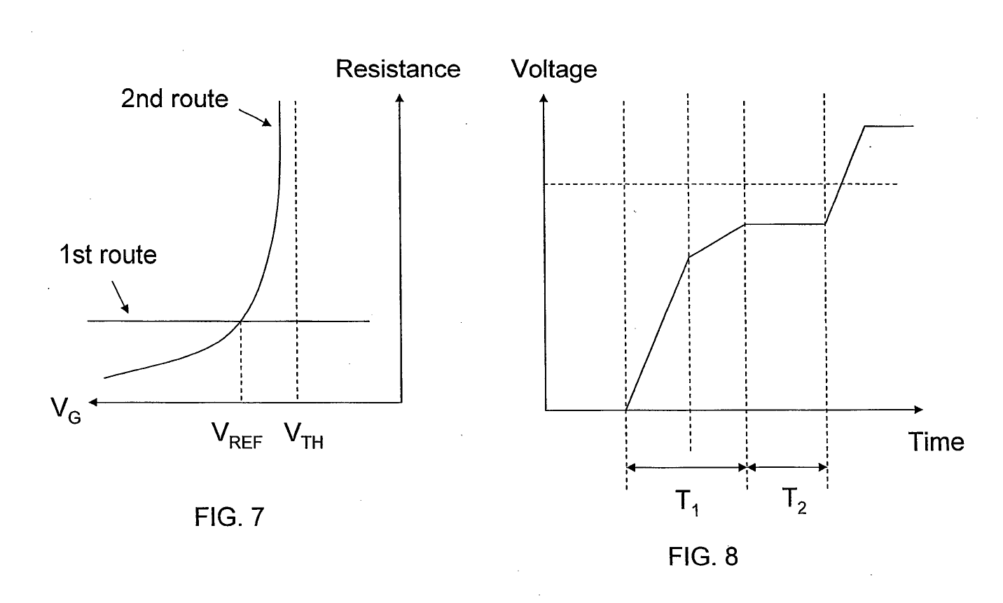

The PMOS 215 acts like a variable resistor but the resistor 220 has a constant resistant. They support two different conduction routes to charge or discharge from the gate of power PMOS 15 to the drain of the PMOS 205. Please refer to FIG. 7, which is resistance curve of a resistor and a PMOS operating in the linear region. The 1st route represents the resistor 220 shown in FIG. 6 and the 2nd route represents the PMOS 215 shown in FIG. 6. As FIG. 7 shows, resistance of the 2nd route is decreased when the gate voltage V_{G} of the power PMOS 15 is decreased. If the gate voltage V_{GS} approaches the threshold voltage V_{TH} of PMOS 215, resistance of PMOS 215 approaches infinity, while the resistance of the 1st route is always constant. The two curves cross each other when the gate voltage V_{G} equals a reference voltage V_{REF}, that is, when the gate voltage V_{G} is less than the reference voltage V_{REF}, resistance of the 1st route is greater than resistance of the 2nd route; when the gate voltage V_{G} is greater than the reference voltage V_{REF}, resistance of the 2nd route is greater than resistance of the 1st route. Therefore, the resistor 220 and the PMOS 215 provide two conduction routes for current flow from the gate of the power PMOS 15 to the drain of the PMOS 205.

The current prefers to flow through the lower resistance conduction route. Therefore, more current flows through the PMOS 215 when the gate voltage V_{G} is less than the reference voltage V_{REF}, and less current flows through the resistor 220 when the gate voltage V_{G} is greater than the reference voltage V_{REF}. Please refer to FIG. 8, which is a voltage diagram of gate voltages of power NMOS shown in FIG. 6 corresponding to this invention. Similar to FIG. 5, the gate voltage V_{G} of the power PMOS 15 is not a simple straight line in period T₁. T₁ of the gate voltage V_{G} curve shown in FIG. 8 is divided into two parts due to the two conduction routes provided in FIG. 6. At beginning, the gate voltage V_{G} is at low level. When the control signal changes from high to low, V_{G} increases but still less than the reference voltage V_{REF}, most charge stored at gate of the power PMOS 15 flows through the low-resistance conduction route, that is, the PMOS 215, to the PMOS 205 and then to power supply. Continuously, the gate voltage V_{G} still increases and greater than the reference voltage V_{REF} but stops near the threshold voltage V_{TH}, most remaining charge stored at gate of the power PMOS 15 flows through the resistor 220 instead of the PMOS 215 to the PMOS 205. Because T₁ is flexibly adjusted and T₂ keeps almost the same, the transition time is controlled to balance the EMI issue and the output signal distortion.

Although the invention has been described in terms of exemplary embodiments, it is not limited thereto. Rather, the appended claims should be construed broadly to include other variants and embodiments of the invention that may be made by those skilled in the art without departing from the scope and range of equivalents of the invention.

What is claimed is:

1. A gate driver for switching power MOSFET, comprising:
a MOS pair, for controlling turning on or turning off the power MOSFET;
a first conduction path electrically coupling to gate of the power MOSFET and the MOS pair, having a constant resistance; and
a second conduction path electrically coupling to gate of the power MOSFET and the MOS pair, having variable resistance corresponding to gate voltage of the power MOSFET.

2. The gate driver of claim 1, wherein the first conduction path is a resistive component.

3. The gate driver of claim 2, wherein the resistive component is a polysilicon resistor.

4. The gate driver of claim 1, wherein the MOS pair comprises a PMOS and a NMOS.

5. The gate driver of claim 1, wherein the second conduction path is a MOS whose gate and drain are connected together.

6. The gate driver of claim 5, wherein the power MOSFET is a power NMOS, the MOS pair comprises a PMOS and a NMOS, the first conduction path is a resistor, and the second conduction path is a NMOS.

7. The gate driver of claim 6, wherein one terminal of the resistor electrically coupled to gate of the power MOSFET, gate and drain of the NMOS of the second conduction path, and drain of the PMOS of the MOS pair; the other terminal of the resistor electrically coupled to source of the NMOS of the second conduction path and drain of the NMOS of the MOS pair; and gates of the PMOS and NMOS of the MOS pair is electrically coupled for receiving a control signal.

8. The gate driver of claim 5, wherein the power MOSFET is a power PMOS, the MOS pair comprises a PMOS and a NMOS, the first conduction path is a resistor, and the second conduction path is a PMOS.

9. The gate driver of claim 8, wherein one terminal of the resistor electrically coupled to gate of the power MOSFET, gate and drain of the PMOS of the second conduction path, and drain of the NMOS of the MOS pair; the other terminal of the resistor electrically coupled to source of the PMOS of the second conduction path and drain of the PMOS of the MOS pair; and gates of the PMOS and NMOS of the MOS pair is electrically coupled for receiving a control signal.

10. The gate driver of claim 1, wherein the resistance of the second conduction path is lower than resistance of the first conduction path according to comparison result of the gate voltage of the power MOSFET and a reference voltage.
